(19) United States
(12) Patent Application Publication
(10) Pub. No.: US 2025/0089193 A1
(43) Pub. Date: Mar. 13, 2025

(54) DIRT-PROOF ELECTRIC CONNECTION BETWEEN TWO INSTALLATION AREAS

(71) Applicant: Schaeffler Technologies AG & Co. KG, Herzogenaurach (DE)

(72) Inventors: Andreas Wascher, Zirndorf (DE); Harald Doerrer, Lonnerstadt (DE)

(73) Assignee: Schaeffler Technologies AG & Co. KG, Herzogenaurach (DE)

(21) Appl. No.: 18/728,460

(22) PCT Filed: Jan. 24, 2023
(86) PCT No.: PCT/DE2023/100053

§ 371 Date: Jul. 12, 2024

(30) Foreign Application Priority Data
Jan. 27, 2022 (DE) 10 2022 101 839.3

(51) Int. Cl. H05K 5/06; H05K 5/02

(52) U.S. Cl. CPC H05K 5/069; H05K 5/0247

(57) ABSTRACT

A dirt-proof electric connection between a first installation area and a second installation area of a component is provided. The connection is characterized in that a printed circuit board is provided with a plastic encapsulation. The plastic encapsulation is designed to rest internally against a wall of the housing of a component in a first transversal direction and in a second transversal direction.

### CROSS-REFERENCE TO RELATED APPLICATIONS

This application is the U.S. National Phase of PCT Appln. No. PCT/DE2023/100053 filed Jan. 24, 2023, which claims priority to DE 10 2022 101 839.3 filed Jan. 27, 2022, the entire disclosures of which are incorporated by reference herein.

### TECHNICAL FIELD

The disclosure relates to a dirt-proof electric connection between a first installation area and a second installation area of a component. The component defines a housing with a surrounding housing wall.

### BACKGROUND

DE 10 2018 104 754 A1 relates to a sealing arrangement for sealing a space between a first machine element and a second machine element which is movable in relation to the first machine element. The sealing arrangement is characterized by a circuit board which serves to establish an electrically conductive connection between the first and the second machine element. The circuit board consists of an electrically conductive fiber fabric embedded in an elastomer matrix.

DE 20 2009 012 606 U1 relates to an inverter with a housing for accommodating the electrical components of the inverter. A further housing having electrical components is provided, wherein a circuit board is provided as an electrical connection between the electrical components in the housing of the inverter and the electrical components in the further housing, which circuit board is sealed at least with respect to the one housing.

### SUMMARY

The object of the disclosure is to separate two installation areas of an electrical component with different contamination classes in a dust-tight and reliable manner, wherein the separation should take up little installation area.

This object is achieved by a dirt-proof electric connection which comprises the features described herein. The disclosure and drawings provide further advantageous embodiments.

According to one embodiment, the dirt-proof electric connection represents an electrical connection between a first installation area and a second installation area of a component, which are spatially separated from one another. The component has a housing with a surrounding housing wall. A printed circuit board with a first free end and a second free end connects the first installation area and the second installation area. At least one plug is electrically conductively connected to the printed circuit board at the first free end or at the second free end. Conductor tracks on a surface of the printed circuit board electrically conductively connect the plugs at the first free end and the second free end. A plastic encapsulation is provided between the first free end and the second free end of the printed circuit board and surrounds them. The plastic encapsulation is applied to an inner side of the housing walls of the housing of the component in a first transversal direction and a second transversal direction and separates the first installation area and the second installation area.

The advantage of such a dirt-proof electric connection is that two installation areas with different contamination classes can be separated from each other in a dust-free manner by the plastic encapsulation described above. The separation is implemented in a small installation area.

According to one embodiment, the plastic encapsulation is designed such that the plugs remain free of the plastic encapsulation. This has the advantage that the plugs are not mechanically affected by thermal expansion of the plastic encapsulation.

According to an advantageous embodiment, the electrical connections of the plugs are connected to the conductor tracks on the surface of the printed circuit board via soldering points. The plastic encapsulation is advantageously designed in a longitudinal direction of the housing in such a way that the soldering points, preferably also the electrical connections and consequently also the plugs, remain free of the plastic encapsulation. This has the advantage that when the plastic encapsulation expands thermally, the soldering points or the electrical connections of the plugs are not broken off by the mechanical stress. Depending on the design of the dirt-proof electric connection, the extension of the plastic encapsulation can be designed in the longitudinal direction.

According to a further embodiment, the printed circuit board has at least one anchor element, in particular on opposite longitudinal sides which rest transversely to the sides of the printed circuit board with the plugs. Each anchor element interacts positively with the plastic encapsulation. The anchor element can take different forms. For example, the anchor element can be a contour made up of elevations and depressions that extends along the respective longitudinal side of the printed circuit board. Likewise, individual, separate bulges (elevations) or notches (depressions) in the longitudinal sides of the printed circuit board can be formed as anchor elements. The anchor elements on the longitudinal sides of the printed circuit board have the advantage that when the plastic encapsulation thermally expands, the printed circuit board is prevented from moving in the material of the plastic encapsulation.

According to a further embodiment, the plugs are provided with supports. The supports can be screws or clips or an adhesive that holds the plugs to the printed circuit board. The supports have the advantage that they can absorb the oscillating mass of the plugs in the event of vibrations, thus preventing mechanical damage to the electrical connection between the plugs and the respective conductor tracks on the printed circuit board.

According to one embodiment, the printed circuit board is an FR4 circuit board. At least on the surface, in addition to the required conductor tracks, a plurality of extended copper surfaces are formed, which extend from the first free end to the second free end of the printed circuit board. The FR4 circuit board can, for example, be a laminate made from four layers.

The extended or large as possible copper areas in the layout of the surface of the printed circuit board have an advantageous effect in that the thermal behavior of the printed circuit board can be evenly distributed over the entire surface.

According to one embodiment, the material of the printed circuit board or circuit board has a glass transition temperature that is higher than the temperature of the plastic encapsulation during injection. The material of the printed circuit board or circuit board should be TG 150 or higher. This has the advantage that when the plastic encapsulation is produced, the printed circuit board or circuit board does not warp or change shape due to thermal softening, and therefore remains dimensionally stable.

The disclosure and its advantages are described in more detail below with reference to the accompanying schematic drawings.

### BRIEF DESCRIPTION OF THE DRAWINGS

FIG. 1 shows a plan view of a possible embodiment of a printed circuit board for designing a dirt-proof electric connection.

FIG. 2 shows a plan view of the embodiment of the printed circuit board from FIG. 1, which is provided with a plastic encapsulation in this embodiment.

FIG. 3 shows a perspective view of the configuration of the dirt-proof electric connection design of FIG. 1.

FIG. 4 shows a plan view of a portion of the dirt-proof electric connection to illustrate the attachment of a plug.

FIG. 5 shows a side view of a portion of the dirt-proof electric connection to illustrate the attachment of a plug.

### DETAILED DESCRIPTION

The exemplary embodiments of the disclosure and the advantages thereof are explained in more detail below with reference to the accompanying figures. The proportions in the figures do not always correspond to the real proportions, since some shapes are simplified and other shapes are shown enlarged relative to other elements for better illustration.

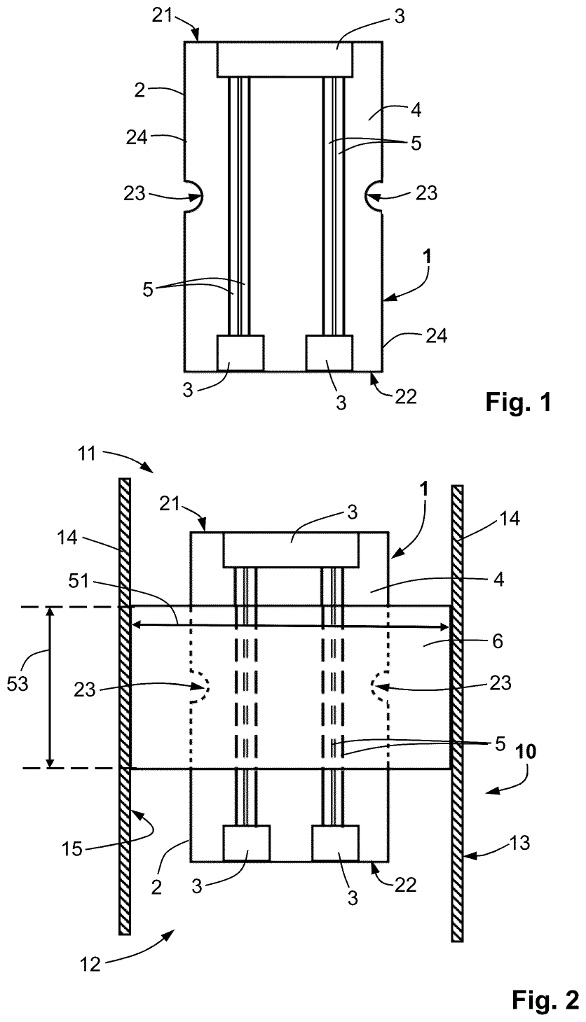

FIG. 1 shows a plan view of a possible embodiment of a printed circuit board 2 for designing a dirt-proof electric connection 1. The printed circuit board 2 defines a first free end 21 and a second free end 22. In the embodiment of the connection 1 shown here, a plug 3 is attached to the first free end 21 on the printed circuit board 2. At the second free end 22 of the printed circuit board 2, two plugs 3 are attached to the printed circuit board 2. The plug 3 at the first free end 21 is electrically conductively connected to the two plugs 3 at the second free end 22. For this purpose, according to the respective data transmission requirements, a plurality of conductor tracks 5 are produced on a surface 4 of the printed circuit board 2 by means of a structuring process from the prior art. The representation shown here of one plug 3 at the first free end 21 and two plugs 3 at the second free end 22 is for description purposes only and should not be construed as a limitation of the disclosure.

Furthermore, the printed circuit board 2 has at least two opposing anchor elements 23 formed on the longitudinal sides 24, which anchor elements 23 prevent the printed circuit board 2 from moving in the plastic encapsulation 6 (see FIG. 2) in the event of thermal expansion. In the embodiment shown here, the two anchor elements 23 are designed as notches, which of course is not to be understood as a limitation of the disclosure. The number and shape of the anchor elements 23 can be selected as desired. For example, a contour on the longitudinal sides 24 of the printed circuit board 2 can be designed with a plurality of bulges and/or notches. It is obvious to a person skilled in the art that the number and shape of the anchor elements 23 shown here should not be construed as a limitation of the disclosure.

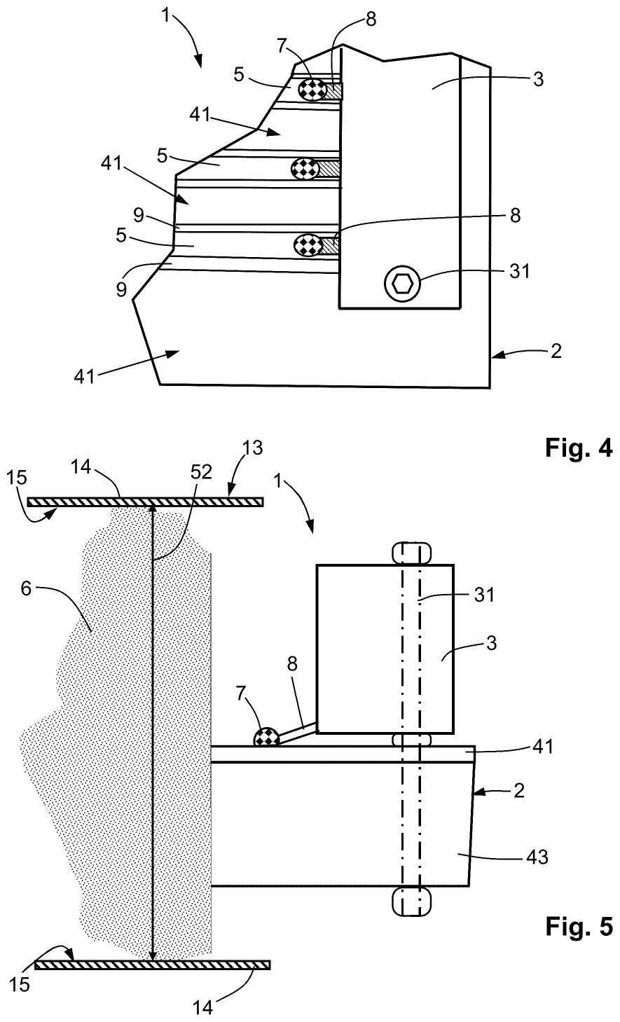

FIG. 2 shows a plan view of the embodiment of the printed circuit board 2 from FIG. 1, which is provided with an embodiment of a plastic encapsulation 6. The plastic encapsulation 6 is attached to the printed circuit board 2 in such a way that the plastic encapsulation 6 surrounds the printed circuit board 2 between the first free end 21 and the second free end 22 and extends in a longitudinal direction 53 of the printed circuit board 3 in the housing 13. The plastic encapsulation 6 extends in the longitudinal direction 53 such that the plugs 3 or the solder contacts 7 thereof (see FIGS. 4 and 5) remain free from the plastic encapsulation 6. The plastic encapsulation 6 rests in a first transversal direction 51 and in a second transversal direction 52 (see FIG. 5), which is perpendicular to the first transversal direction 51, on an inner side 15 of the housing walls 14 of the housing 13 of the component 10. The plastic encapsulation 6 divides the component 10 into the first installation area 11 and the second installation area 12.

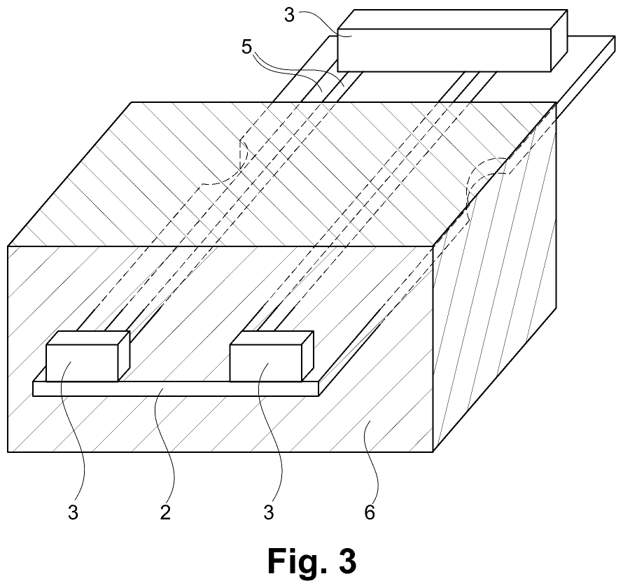

A perspective view of the design of the dirt-proof electric connection 1 from FIG. 1 is shown in FIG. 3. The conductor tracks 5 on the surface 4 of the printed circuit board 2 run from the plug 3 at the first free end 21 to two plugs 3 at the second free end 22. The plastic encapsulation 6 partially covers the conductor tracks 5. The housing 13 with the housing walls 14 is not shown here for the sake of clarity. All other components and elements of connection 1 are already shown in FIGS. 1 and 2, so a further description is omitted here for the sake of simplicity.

FIG. 4 shows a plan view of a portion of the dirt-proof electric connection 1 to illustrate the attachment of a plug 3. FIG. 5 shows a side view of a portion of the dirt-proof electric connection 1 to illustrate the attachment of a plug 3. Likewise, the housing walls 14 of the housing 13 are only partially shown. As already mentioned in the description of FIG. 2, the plastic encapsulation 6 rests in a second transversal direction 52 on the inner side 15 of the wall 14 of the housing 13 of the component 10.

All other plugs 3 of the dirt-proof electric connection 1 can be attached in the same way. Each plug 3 is attached to the printed circuit board 2 via at least one support 31 (in FIG. 5, however, the support 31 is only indicated as a dot-dash line, since it runs within the plug 3 and within the base material 43 of the printed circuit board 2, i.e., is actually not visible in these areas 3, 43 in the side view). The supports 31 can be designed, for example, as screws or clips or as an adhesive. The supports 31 are provided to absorb the oscillating mass of the plugs 3 in the event of vibrations. The electrical connection of the plugs 3 to the printed circuit board 2 is made via electrical connections 8, which are connected to corresponding conductor tracks 5 via a soldering point 7. Furthermore, a plurality of copper surfaces 41 are formed on the surface 4 of the printed circuit board 2. The copper surfaces 41 should have the largest possible areas on the printed circuit board 2 to distribute the thermal behavior of the printed circuit board 2 evenly over the entire surface 4 of the printed circuit board 2. The base material 43 of the printed circuit board 2 is, for example, an FR4 circuit board which has the conductor tracks 5 (made of copper) and the plurality of copper surfaces 41 formed on at least one of the surfaces 4 of the printed circuit board 2.

It is believed that the present disclosure and many of the advantages noted therein will be understandable from the preceding description. It will be apparent that various changes in the shape, construction and arrangement of the components can be made without departing from the disclosed subject matter. The form described is illustrative only and it is the intent of the appended claims to comprise and incorporate such changes. Accordingly, the scope of the disclosure should be limited only by the appended claims.

### LIST OF REFERENCE SYMBOLS

1 Connection
2 Printed circuit board
3 Plug
4 Surface
5 Conductor track
6 Plastic encapsulation
7 Soldering point
8 Electrical connection
9 Structuring
10 Component
11 First installation area
12 Second installation area
13 Housing
14 Housing wall
15 Inside
21 First free end
22 Second free end
23 Anchor element, notch
24 Longitudinal side
31 Support
41 Copper layer
43 Base material
51 First transversal direction
52 Second transversal direction
53 Longitudinal direction

1. A dirt-proof electric connection between a first installation area and a second installation area of a component, which comprising:
a housing having surrounding walls,
a printed circuit board with a first free end and a second free end, wherein the printed circuit board connects the first installation area and the second installation area;
at least one plug; which is electrically connected to the printed circuit board at the first free end or at the second free end, wherein conductor tracks on a surface of the printed circuit board electrically conductively connect the at least one plug at the first free end and the second free end; and
a plastic encapsulation which seals the printed circuit board between the first free end and the second free end, and rests against an inner side of the walls of the housing of the component in a first transversal direction and a second transversal direction.

2. The dirt-proof electric connection according to claim 1, wherein the plastic encapsulation is designed such that the at least one plug remains free from the plastic encapsulation.

3. The dirt-proof electric connection according to claim 1, wherein an electrical connection of the at least one plugs are connected via soldering points to the conductor tracks on the surface of the printed circuit board and the plastic encapsulation is formed in a longitudinal direction of the housing such that the soldering points remain free of the plastic encapsulation.

4. The dirt-proof electric connection according to one claim 1, wherein the printed circuit board has at least two opposing anchor elements with which the plastic encapsulation interacts in a form-fitting manner.

5. The dirt-proof electric connection according to claim 1, wherein the at least one plug are is provided with supports.

6. The dirt-proof electric connection according to claim 1, wherein the supports are screws or clips or adhesives.

7. The dirt-proof electric connection according to claim 1, wherein the printed circuit board is an FR4 circuit board which comprises a plurality of copper surfaces at least on the surface which has formed the conductor tracks.

8. The dirt-proof electric connection according to claim 1, wherein a material of the printed circuit board has a glass transition temperature which is higher than a temperature of the plastic encapsulation during injection.

9. The dirt-proof electric connection according to claim 8, wherein the material of the printed circuit board is TG 150 or higher.
